(19) United States
(12) Patent Application Publication
(10) Pub. No.: US 2003/0053578 A1
(43) Pub. Date: Mar. 20, 2003

(54) Synchronous receiver

(75) Inventors: Todd A. Hinck, Cambridge, MA (US); William B. Gist, Chelmsford, MA (US); Hiep Ngo, Boston, MA (US)

Correspondence Address: LAHIVE & COCKFIELD, 28 STATE STREET, BOSTON, MA, 02109, US

(73) Assignee: Sun Microsystems, Inc., Palo Alto, CA (US)

(21) Appl. No.: 09/954,799

(22) Filed: Sep. 18, 2001

(51) Int. Cl. H03D 3/24

(52) U.S. Cl. 375/376

(57) ABSTRACT

An electronic apparatus for receiving source synchronous signals is provided. The receiver continuously monitors the phase relationship between each data signal and the source synchronous clock signal. In this manner, the electronic apparatus can compensate for phase discrepancies that occur over time without having to interrupt any data operations.

### TECHNICAL FIELD OF THE INVENTION

The present invention generally relates to synchronous communications and more particularly, to a receiver for receiving synchronous communications.

### BACKGROUND OF THE INVENTION

As electronic component fabrication technology advances, electronic components are becoming smaller, faster, and more complex. Nevertheless, the technological advances in communication mediums, such as printed circuit board interconnections have not been as dramatic. Consequently, the speed at which newly fabricated electronic devices transmit and receive data have surpassed the transmission capabilities of printed circuit board interconnections, especially between clusters of microprocessors and affiliated components, such as memory and other input/output components mounted to a printed circuit board. To compensate for the limited bandwidth of a single transmission path carrying multiple bits of data over printed circuit board interconnections, design engineers and system architects have begun to establish the use of parallel paths, also known as a dedicated, point-to-point transmission paths for each data bit to counter the bandwidth limitations.

Unlike serially transmitted bits of data that typically include timing information for each data bit, synchronous point-to-point communications require the transmitting device to provide a source synchronous clock signal for timing purposes by the receiving electronic device. The source synchronous clock signal typically has a predetermined phase relationship to the parallel transmitted data. At transmission speeds below 200 Mb/s/pin, the phase relationship between the source synchronous clock signal and the parallel data signal does not need to be tightly coupled to result in correct interpretation of the data by the receiving electronic device. However, as data transmission speeds increase towards 700 Mb/s/pin and beyond, most source synchronous systems implement the use of a capture period or a sampling window to determine the value of the incoming data. The use of a capture period or sampling window allows the system to compensate for predetermined phase discrepancies between the source synchronous clock signal and the data signal. Unfortunately, phase discrepancies between the source synchronous clock signal and one or more of the parallel data signals can occur during transmission and cause the receiving electronic device to misinterpret a received data bit.

Typically, the receiving electronic device in a point-to-point communication architecture utilizes a sampling receiver architecture that samples once per bit cycle. Unfortunately, noise often occurs during sampling and causes the sampling receiver to resolve to the wrong value of the received data bit.

### SUMMARY OF THE INVENTION

The present invention addresses the above-described limitations of conventional receivers in point-to-point communication architectures. The present invention provides an approach to enable a receiver in a point-to-point communication system to overcome phase discrepancies between the source synchronous clock signal and the one or more received data signals to avoid false data values attributable to either noise during data sampling or phase discrepancies.

In one embodiment of the present invention, an apparatus for receiving a synchronous signal is provided. The apparatus includes a receiver circuit for receiving the data bits from the transmitting source and a feedback circuit. The feedback circuit provides the feedback to allow the receiver to continuously synchronize the source synchronous clock with each received data signal to avoid phase discrepancies. The receiver circuit includes three integrating circuits to perform the synchronization and data value determination of the received data signal. Two of the integrating circuits each receive a phase shifted version of the incoming source synchronous clock signal to integrate with the received data signal. The first integrating circuit receives a version of the source synchronous clock signal that is slightly advanced while the second integrating circuit receives a version of source synchronous clock signal that is slightly delayed. The third integrating circuit receives a version of the source synchronous clock signal that falls in the middle of the advanced and the delayed version of the source synchronous signal.

The output of the integrating circuit that receives the advanced version of the source synchronous signal clock signal and the output of the integrating circuit that receives the delayed version of the source synchronous clock signal are subtracted from one another to generate an error signal. This error signal is applied to a loop filter to remove any AC voltage component. The loop filter provides to the phase interpolator the corresponding DC voltage value. The phase interpolator, based on the provided DC voltage value, selects from a voltage controlled oscillator a first course clock and a second course clock. The phase interpolator in turn asserts a fine clock signal, the integration clock signal, a fine clock signal with a positive offset, the advanced source clock signal, and a fine clock signal with a negative offset, the delayed source clock signal.

The above-described approach benefits a system architecture that utilizes multiple microprocessors, memory arrays, and other like devices that communicate in a point-to-point manner because a receiving device can continuously compensate for phase shifts in the source synchronous clock signal and the multiple data signals in real time. Such system architectures benefit multiprocessor server systems because the architecture can continuously compensate for phase shifts that occur during data transmission to avoid false data interpretation at the receiving device. Moreover, the receiving device is able to integrate the received data signal over the entire clock period of the source synchronous clock to avoid the effects of transient noise or switching noise that can cause the receiver to resolve to a false data value. Further, the system architect and design engineer may utilize a multi-level signaling protocol for point-to-point data transmission to compensate for transmission medium frequency limitations.

In accordance with another aspect of the present invention, a method is performed that allows a receiver in a source synchronous, point-to-point communication system to compensate for phase differences between the source synchronous clock signal and a data signal in real time. For each received data signal, the receiver integrates the received data signal across three versions of the source synchronous clock signal. The first version of the source synchronous clock signal is an advanced version of the source synchronous clock signal to detect an early arriving data signal relative to the source synchronous clock signal. The second version is a delayed version of the source synchronous clock signal to detect a late arriving data signal relative to the source synchronous clock signal. While the third version of the source synchronous clock signal is a version that has been shifted to align with an average of several previous data edges.

To align the source synchronous clock signal with the received data signal, a first receiver integrates the advanced version of the source synchronous clock signal with the received data signal to determine a first data value. In parallel, the delayed version of the source synchronous clock signal and the received data signal are integrated by a second receiver to determine a second data value. A difference in magnitude is then determined between the first data value and the second data value to determine the phase variation between the source synchronous clock signal and the received data signal. The magnitude difference is filtered to produce a DC voltage value. The DC voltage value is passed to a phase interpolator, which, based on the DC voltage value selects from a voltage controlled oscillator a first course clock and a second course clock to generate the advanced offset version of the source synchronous clock signal, the delayed offset version of the source synchronous clock signal, and the version of the source synchronous clock signal that falls between the advanced and the delayed version.

While the phase variation between the source synchronous clock signal and the received data signal is being determined, the receiver is also integrating the received data signal over the third version of the source synchronous clock signal to produce a data value for the received data signal. The third version of the source synchronous clock signal is phase shifted to synchronize with the received data signal based on the phase variation determined for a series of previously received data signals.

The above-described approach benefits a microprocessor architecture utilizing parallel circuit board traces as a transmission medium. In this manner, the architecture maximizes the bandwidth capability of the printed circuit board transmission medium. Moreover, this approach constantly monitors each transmission path to detect and adjust for phase discrepancies that occur between the source synchronous clock signal and each data signal to continuously compensate for the effects of cross talk and variations in transmission path capacitance.

### BRIEF DESCRIPTION OF THE DRAWINGS

An illustrative embodiment of the present invention will be described below relative to the following drawings.

FIG. 1 depicts a block diagram of a point-to-point communication system suitable for practicing the illustrative embodiment of the present invention.

FIG. 2 depicts a receiver apparatus that is suitable for implementing the illustrative embodiment of the present invention.

FIG. 3 depicts the phase relationship of the source synchronous clock signal to the received data signal.

FIG. 4 is a flow diagram depicting the steps taken to practice the illustrative embodiment of the present invention.

### DETAILED DESCRIPTION OF THE ILLUSTRATIVE EMBODIMENT

The illustrative embodiment of the present invention provides a receiver architecture to continuously compensate for phase discrepancies between a source synchronous clock signal and a data signal in a point-to-point communications system. In the illustrative embodiment, an apparatus is adapted to have a receiver for receiving a source synchronous data signal which may be binary or multi-level and a source synchronous clock signal. For each point-to-point transmission path, the receiver performs three integrations of the received data signal using a first integrating detector, a second integrating detector, and a third integrating detector. The output of the first integrating and the second integrating detector are combined to determine for a single transmission path, the phase relationship of the received data signal and the offset source synchronous clock signals provided to the first and second integrating detector. The phase relationship is filtered and provided to a phase interpolator for selection of a first course clock signal and a second course clock signal from a voltage controlled oscillator to generate an integration source synchronous clock signal that is synchronized or in phase to that line's received data signal. The integration source synchronous clock signal is provided to the third integrating detector for integration with the received data signal to allow the third integrating detector to integrate the received data signal across the entire period of the source synchronous clock signal to determine the data value of the received data signal.

In the illustrative embodiment, the apparatus is attractive for use in a multiple microprocessor server architecture where the multiple microprocessors communicate with each other in a source synchronous point-to-point manner. The apparatus also allows a multi-microprocessor server to maximize the bandwidth of printed circuit board transmission paths by utilizing a multi-level communications protocol and avoids a receiver vulnerable to noise events that can corrupt the interpretation of transmitted data. Additionally, the illustrative embodiment continuously synchronizes the source synchronous clock signal to each data signal to compensate for phase shifts caused by dynamic events, such as cross talk, transmission path loading, and capacitance effects of data transmission on the transmission paths.

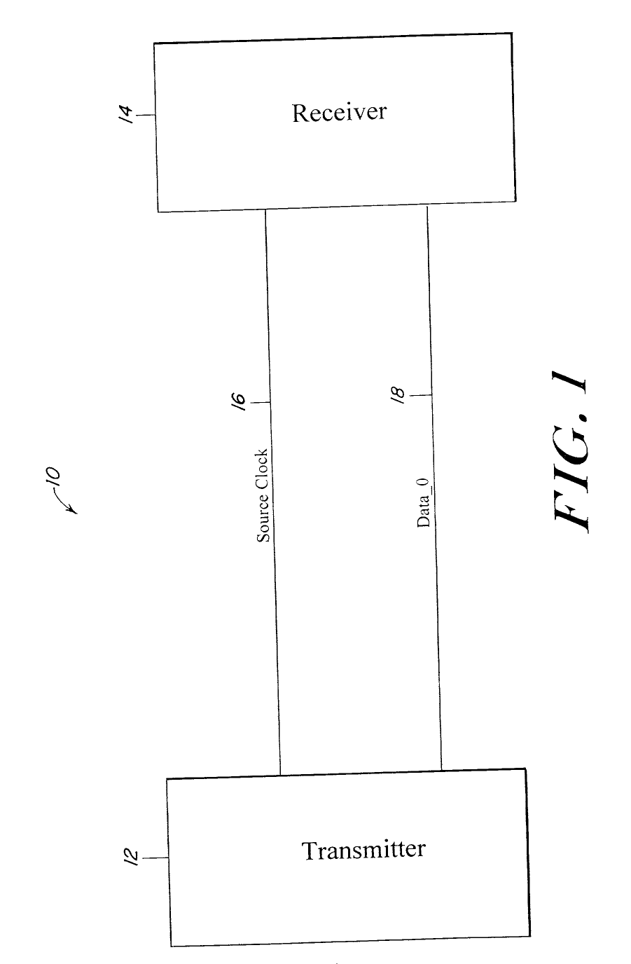

FIG. 1 illustrates an exemplary source synchronous point-to-point communication system 10 that is suitable for the illustrative embodiment of the present invention. The exemplary source synchronous point-to-point communication system 10 includes a transmitter device 12 for transmitting data and a receiver device 14 for receiving the transmitted data.

FIG. 1 illustrates a one bit source synchronous point-to-point communication system. Nevertheless, those skilled in the art will recognize that the exemplary source synchronous point-to-point communication system 10 may include additional data transmission paths, such as four data transmission paths, eight data transmission paths, sixteen data transmission paths, thirty-two data transmission paths, or sixty-four data transmission paths. In like manner, the exemplary source synchronous point-to-point communication system 10 may have as few as one data transmission path.

For ease of the discussion below, the receiver 14 is discussed in relation to the first data transmission path 18. This is not meant to be limiting of the illustrative embodiment of the present invention, but merely meant to facilitate explanation. Those skilled in the art will appreciate that the details discussed below apply equally to the data transmission paths 20, 22, 24, 26, 28, 30, and 32.

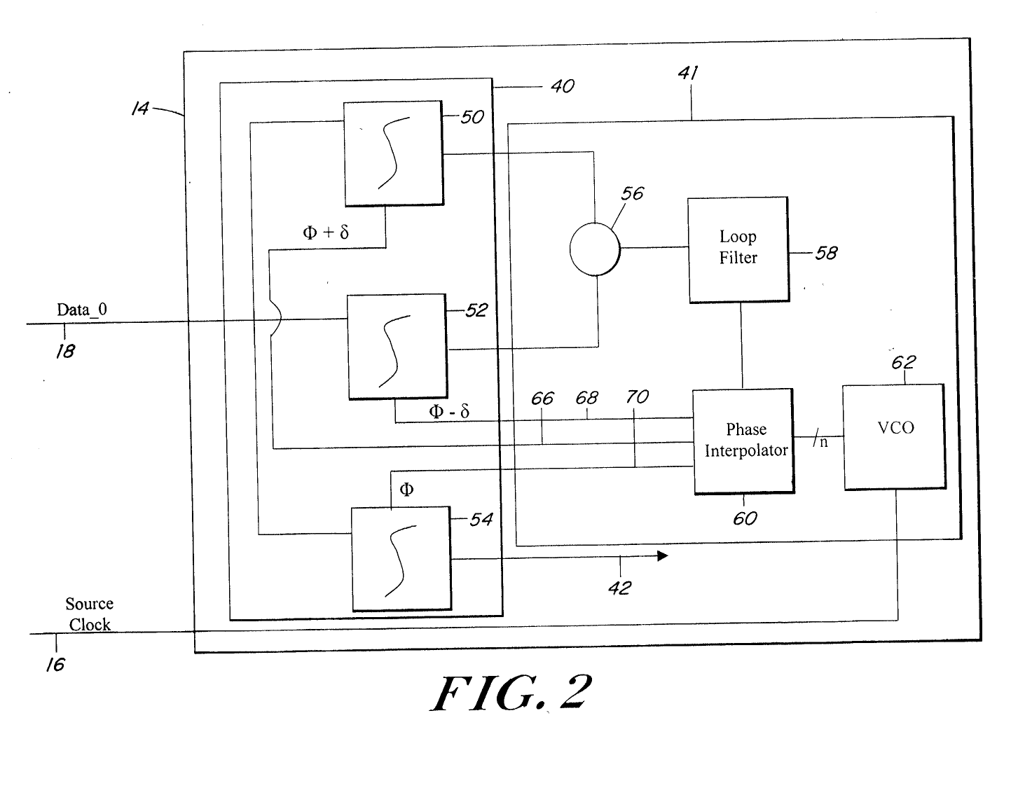

FIG. 2 illustrates the receiver 14 in more detail. Those skilled in the art will recognize that FIG. 2 illustrates the portion of the receiver 14 applicable to the first data transmission path 18 and that the receiver 14 provides a receiver circuit and a feedback circuit, which are discussed below in more detail, for each data transmission path coupled thereto. As illustrated, the receiver 14 includes a receiver circuit 40 and a feedback circuit 41. The receiver circuit 41 is configured to include a first integrating detector 50, a second integrating detector 52, and a third integrating detector 54. The first input of each integrating detector 50, 52, and 54 are coupled to the data transmission path 18, while the source synchronous clock transmission path 16 is coupled to the voltage control oscillator (VCO) 62.

The first integrating detector 50 has its second input coupled to the phase interpolator 60 via the transmission path 66. The second integrating detector 52 has its second input coupled to the phase interpolator 60 via the transmission path 68, and the third integrating detector 54 has its second input coupled to the phase interpolator 60 via the transmission path 70. The output of the first integrating detector 50 and the output of the second integrating detector 52 are coupled to the subtractor 56. The subtractor 56 operates to determine the magnitude difference between the output of first integrating detector 50 and the output of second integrating detector 52 and asserts the magnitude difference to the loop filter 58. The subtractor 56 can be a differential amplifier. One skilled in the art will recognize that the subtractor 56 may be configured as a threshold detector or a RC filter network.

The loop filter 58 filters the magnitude difference asserted by the subtractor 56 to remove any AC voltage component. The loop filter 58 asserts a DC voltage value to the phase interpolator 60 to indicate the phase shift between two versions of the source synchronous clock signal and the received data signal detected by the first integrating detector 50 and the second integrating detector 52. Those skilled in the art will appreciate that the loop filter 58 can be an RC network or other type of filter circuit.

The phase interpolator 60 receives the DC voltage value asserted by the loop filter 58 and interprets the DC voltage value to determine the phase shift necessary to align a version of the source synchronous clock signal and the received data signal. Based on the DC voltage value, the phase interpolator 60 selects from the VCO 62 a first course clock version and a second course clock version and generates three versions of the source synchronous clock signal.

The first version of the source synchronous clock signal that the phase interpolator 60 generates is a version of the source synchronous clock signal that has been advanced in phase relative to the received source synchronous clock signal to emulate an early arriving source synchronous clock signal relative to the data signal. The second version of the source synchronous clock signal that the phase interpolator 60 generates is a version of the source synchronous clock signal that is delayed in phase relative to the received source synchronous clock signal to emulate a late arriving source synchronous clock signal relative to the data signal. The third version of the source synchronous clock signal that the phase interpolator 60 generates is a version of the source synchronous clock signal that is phase shifted to fall in the middle of the first version of the source synchronous clock signal and the second version of the source synchronous clock signal generated by the phase interpolator 60. Those skilled in the art will recognize that the phase interpolator 60 can be configured to generate clock signals with a nominal phase difference of π/8 or π/64 or any other nominal phase difference necessary. Moreover, the number of interconnections between the VCO 62 and the phase interpolator 60 are proportional to the refinement in nominal phase difference that the phase interpolator 60 utilizes.

The third version of the source synchronous clock signal is selected to align with an average of several, such as three or four previously received data signals on the transmission path 18. In this manner, the third integrating detector 54 can integrate across the entire received data signal and avoid the effects of noise ripple, switching noise and transient noise on the data transmission path 18, the source clock transmission path 16 or the receiver 14.

The phase interpolator 60 chooses two course clock signals from the VCO 62 and generates three fine clock signals, the advanced source clock signal 76, the delayed source clock signal 78 and the integration clock signal 79. The phase interpolator 60 combines a finite state machine and a current steering circuit to produce the three fine clock signals. The phase interpolator 60 asserts the first fine version of the source synchronous clock signal on the data transmission path 66 coupled to the first integrating detector 50, asserts the second fine version of the source synchronous clock signal on the transmission path 68 coupled to the second integrating detector 52 and asserts the third fine version of the source synchronous clock signal on the transmission path 70 coupled to the third integrating detector 54.

The first integrating detector 50, the second integrating detector 52 and the third integrating detector 54 are current integrating amplifiers that integrate the data signal provided by the transmitter 12 on the path 18 for a period not greater than the entire period of the corresponding clock signals provided by the phase interpolator 60. . In this manner, the integrating detectors 50, 52, and 54 overcome the effect of noise that occurs during a single or multiple sampling period of the received data signal that causes conventional sampling detectors to assert a false value.

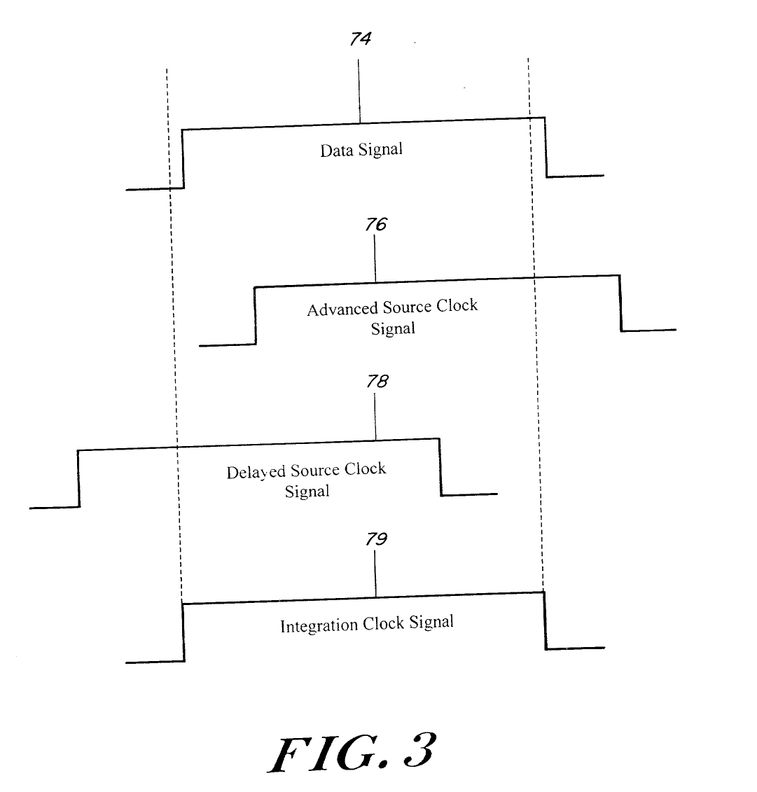

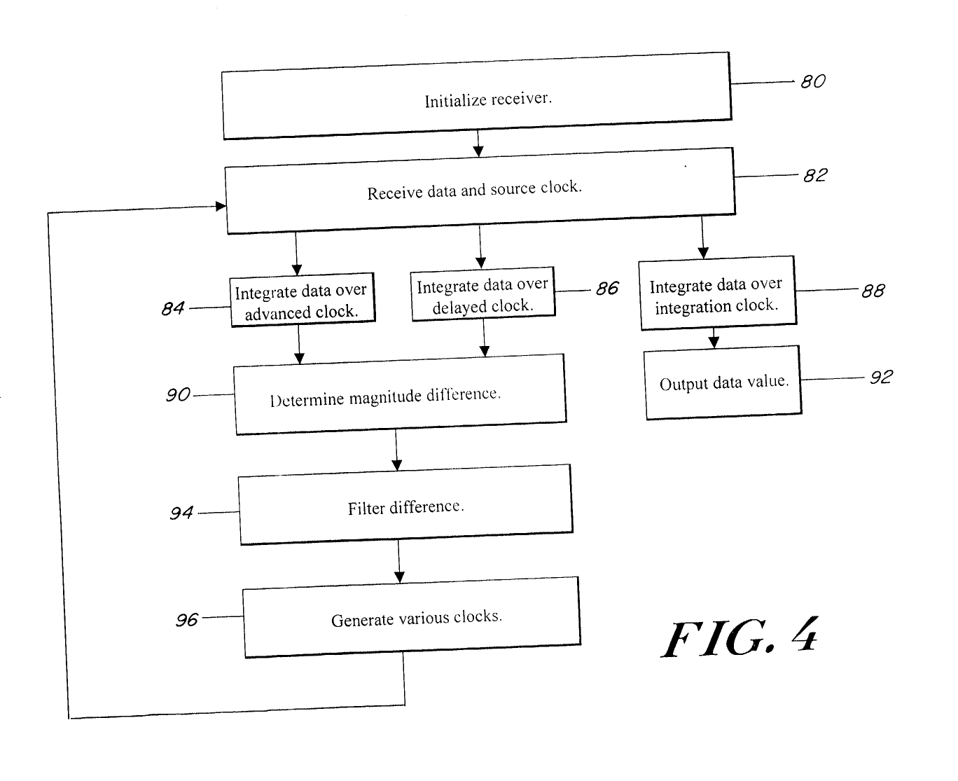

The operation of the receiver 14 is discussed below in more detail with reference to FIG. 3 and FIG. 4. At power on or upon a reset operation of the exemplary source synchronous point-to-point communication system 10, the transmitter 12 transmits a test signal along the transmission path 18 and the source synchronous clock signal along the transmission path 16 to the receiver 14 (step 80 in FIG. 4). In this manner, fixed factors that cause phase discrepancies, such as variation in line length of each transmission path can be measured and compensated for. The receiver 14 utilizes the steps detailed below to initialize the receiver and align the data signal provided by the transmitter 12 with the source synchronous clock signal. The receiver 14 produces the fine clock hereinafter referred to as the integration source clock signal 79 based on the received test data signal or the average of several previously received data signals, such as an average of three or four data signals at the first integrating detector 50 and the second integrating detector 52. As a result, the integration source clock signal 79 that the third integrating detector 54 utilizes to integrate the just received data signal 74 is based on the average phase difference of several previously received data signals on the transmission path 18. Hence, the integration source clock signal 79 accounts for any phase discrepancy between several previously received data signals and the source synchronous clock signal on the transmission path 16. Nevertheless, one of ordinary skill in the art will recognize that the set of several previously received data signals used to determine an average phase differential could include more than three or four data signals. Those skilled in the art will also recognize that during receiver initialization, the transmitter 12 provides the receiver 14 with test data signals on each point-to-point transmission path. Moreover, during receiver initialization, the transmitter 12 provides as many test data signals as necessary to produce a synchronized source synchronous clock signal for each data signal on each data transmission path.

The receiver 14 receives the source synchronous clock signal at the voltage control oscillator 62 and receives the data signal 74 at the first input of the integrating detector 50, the first input of the second integrating detector 52, and the first input of the third integrating detector 54 (step 82 in FIG. 4). The phase interpolator 60, based on an average phase difference between several previously received data signals and several previously received source synchronous clock signals selects from the VCO 62, a first course clock signal and a second course clock signal to generate and assert the advanced source clock signal 76, on the transmission path 66 to the first integrating detector 50 (step 84 in FIG. 4). The first integrating detector 50 integrates the data pulse 74 over the advanced source clock signal 76 to produce a data value (step 84 in FIG. 4). In like manner, the phase interpolator 60 generates from the first course clock signal and the second course clock signal, a delayed source clock signal 78 based on the phase difference between the previously received data signal and the source synchronous clock signal and asserts the delayed source clock signal 78 on the transmission path 68 to the second integrating detector 52 (step 86 in FIG. 4). The second integrating detector 52 integrates the data pulse 74 over the delayed source clock signal 78 to produce a value (step 86 in FIG. 4).

Additionally, the phase interpolator 60 generates from the first course clock signal and the second course clock signal the integration source clock signal 79 and asserts it onto the transmission path 70 to the third integrating detector 54 (step 88 in FIG. 4). The third integrating detector 54 integrates the data signal 74 over the entire period of the synchronized source clock signal 79 (step 88 in FIG. 4) to produce a value of the received data signal 74 on the output path 42 (step 92 in FIG. 4).

The subtractor 56 determines the magnitude difference between the value asserted by the first integrating detector 50 and the value asserted by the second integrating detector 52 and asserts the magnitude difference to the loop filter 58 (step 90 in FIG. 4). The loop filter 58 removes the AC voltage component from the signal asserted by the subtractor 56 to provide the phase interpolator 60 with a DC voltage value that indicates the phase offset of the data pulse 74 and the source synchronous clock signal received by the VCO 62 (step 94 in FIG. 4).

The phase interpolator 60 based on the magnitude of the DC voltage signal provided by the loop filter 58 selects from the VCO 62 the two course versions of the clock signal needed to generate the first version of the source synchronous clock signal depicted as the advanced source clock signal 76 and the second version of the source synchronous clock signal depicted as the delayed source clock signal 78 (step 96 in FIG. 4). In addition, the phase interpolator 60, based on the two selected course clock signals, generates the third version of the source synchronous clock signal that is synchronized to the data signal 74 (step 94 in FIG. 4). The third version of the source synchronous clock signal is depicted as the integration source clock signal 79. As a result, the third integrating detector 54 integrates the data pulse 74 over the entire period of the synchronized source clock signal 79 to ensure correct capture of the value of the data pulse 74.

While the present invention has been described with reference to a preferred embodiment thereof, one skilled in the art will appreciate that various changes in form and detail may be made without departing from the intended scope of the present invention as defined in the pending claims. For example, its receiver 14 may receive a multi-level source synchronous signal, such as a two-level pulse amplitude modulation (2-PAM) signal or a four-level pulse amplitude modulation (4-PAM) signal. Those skilled in the art will recognize that the use of a digital to analog converter (DAC) and an analog to digital converter (ADC) in each transmission path may be necessary for the receiver 14 to process multi-level signals.

1. An apparatus for receiving data of a source synchronous signal and a source synchronous clock signal in a source synchronous point-to-point communication system, said apparatus comprising:
a receiver circuit for receiving said data of said source synchronous signal; and
a feedback circuit for providing said receiver circuit with a plurality of feedback signals based on an output of said receiver circuit to synchronize receipt of said data of said source synchronous signal by said receiver circuit.

2. The apparatus of claim 1, wherein said receiver circuit comprises,
a first integrating detector circuit to integrate said data over a period of time relative to a first feedback signal of said plurality of feedback signals to produce a first output signal;
a second integrating detector circuit to integrate said data over a period of time relative to a second feedback signal of said plurality of feedback signals to produce a second output signal;
a third integrating detector circuit to integrate said data over a period of time relative to a third feedback signal of said plurality of feedback signals to produce a third output signal; and
a differentiating circuit coupled to said first integrating detector circuit and said second integrating detector circuit to determine a difference between said first output signal and said second output signal:

3. The apparatus of claim 1, wherein said feedback circuit comprises,
a filter to remove a voltage component of one of said receiver output signals to assert a filtered signal;
a voltage controlled oscillator for generating a plurality time varying signals; and
a phase interpolator to select one or more of a said plurality of time varying signals from said voltage controlled oscillator based on said filtered signal to provide said receiver with said plurality of feedback signals.

4. The apparatus of claim 2, wherein said first integrating detector circuit and said second integrating detector circuit and said third integrating detector circuit each comprise,
an integrating amplifier to integrate said data of said source synchronous signal relative to one of said plurality of feedback signals to determine a value for said data.

5. The apparatus of claim 2, wherein said first feedback signal of said plurality of feedback signals allows said first integrating detector circuit to determine if said data of said source synchronous signal is advanced in phase relative to said source synchronous clock signal of said source synchronous point-to-point communication system.

6. The apparatus of claim 2, wherein said second feedback signal of said plurality of feedback signals allows said second integrating detector circuit to determine if said data of said source synchronous signal is delayed in phase relative to said source synchronous clock signal of said source synchronous point-to-point communication system.

7. The apparatus of claim 2, wherein said third feedback signal of said plurality of feedback signals allows said third integrating detector circuit to integrate said data of said source synchronous signal relative to an in phase version of said source synchronous clock signal relative to said data.

8. The apparatus of claim 1, wherein said source synchronous signal comprises a multi-level source synchronous signal.

9. The apparatus of claim 3, wherein said voltage component is an alternating current voltage.

10. The apparatus of claim 1, wherein said source synchronous signal is a differential signal.

11. The apparatus of claim 8, wherein said multi-level source synchronous signal comprises one of a two-level pulse amplitude modulation signal and a four-level pulse amplitude modulation signal.

12. A method for continuously synchronizing a source synchronous clock signal on a clock line with a data signal on a data line at a receiver of said source synchronous clock signal and said data line, said method comprising the steps of:
determining at said receiver a phase relationship between said source synchronous clock signal and said data signal each time said receiver receives said source synchronous clock signal and said data signal, and
synchronizing said source synchronous clock signal and said data signal to be in phase at said receiver each time said receiver receives said data signal and said source synchronous clock signal, wherein said synchronization is based on said determined phase relationship between said source synchronous clock signal and said data signal to continuously synchronize said source synchronous clock signal and said data signal to allow said receiver to integrate said data signal over an entire period of said clock signal.

13. The method of claim 12, wherein said phase relationship between said source synchronous clock signal and said data signal is determined by the steps of:
shifting said source synchronous clock signal in a first direction relative to said source synchronous clock signal as received by said receiver and integrating said source synchronous clock signal shifted in said first direction together with said data signal to produce a first output signal;
shifting said source synchronous clock signal in a second direction relative to said source synchronous clock signal as received by said receiver and integrating said source synchronous clock signal shifted in said second direction together with said data signal to produce a second output signal; and
determining a magnitude difference between said first output signal and said second output signal to determine said phase relationship between said source synchronous clock signal and said data signal.

14. The method of claim 13, further comprising the steps of,
shifting said source synchronous clock signal in a desired direction based on said magnitude difference between said first output signal and said second output signal to synchronize an edge of said data signal with an edge of said source synchronous clock signal; and
integrating said source synchronous clock signal synchronized to said data signal over an entire period of said source synchronous clock signal to determine a value for said data signal.

15. The method of claim 13, wherein a phase interpolator circuit based on said magnitude difference between said first output signal and said second output signal selects from a voltage controlled oscillator a first course clock signal and a second course clock signal to generate said source synchronous clock signal shifted in said first direction and said source synchronous clock signal shifted in said second direction.

16. The method of claim 15, wherein said phase interpolator circuit further generates said source synchronous clock signal synchronized to said data signal based on said magnitude difference between said first output signal and said second output signal.

17. The method of claim 13, wherein a differential amplifier determines said magnitude difference between said first output signal and said second output signal.

18. The method of claim 13, further comprising the step of filtering said determined magnitude difference between said first output signal and said second output signal to remove a particular voltage component of said determined magnitude difference.

19. The method of claim 15, wherein said source synchronous clock signal drives said voltage controlled oscillator to provide said phase interpolator circuit with said first course clock signal and said second course clock signal to allow said phase interpolator circuit to generate said source synchronous clock signal shifted in said first direction, said source synchronous clock signal shifted in said second direction, and said source synchronous clock signal synchronized to said data signal.

20. The method of claim 15, wherein said source synchronous clock signal drives a phase lock loop circuit to provide said phase interpolator circuit with a plurality of signals to allow said phase interpolator circuit to generate said source synchronous clock signal shifted in said first direction, said source synchronous clock signal shifted in said second direction, and said source synchronous clock signal synchronized to said data signal.

21. The method of claim 12, wherein said data signal is a differential signal.

22. The method of claim 12, wherein said source clock signal is a differential clock signal.

23. The method of claim 12, wherein said data signal comprises a multi-level source synchronous signal.

24. The method of claim 23, wherein said multi-level source synchronous signal comprises one of a two-level pulse amplitude modulation signal and a four-level pulse amplitude modulation signal.
